(19) United States
(12) Patent Application Publication
(10) Pub. No.: US 2013/0076356 A1
(43) Pub. Date: Mar. 28, 2013

(54) MAGNETIC RESONANCE IMAGING METHOD AND APPARATUS TO CORRECT DISTORTIONS DUE TO INHOMOGENEITIES OF THE BASIC MAGNETIC FIELD

(71) Applicants: Vladimir Jellus, Kirchehrenbach (DE); Lars Lauer, Neunkirchen (DE); Mathias Nittka, Baiersdorf (DE)

(72) Inventors: Vladimir Jellus, Kirchehrenbach (DE); Lars Lauer, Neunkirchen (DE); Mathias Nittka, Baiersdorf (DE)

(21) Appl. No.: 13/627,273

(22) Filed: Sep. 26, 2012

(30) Foreign Application Priority Data
Sep. 26, 2011 (DE) 102011083395.1

(51) Int. Cl. G01R 33/56; G01R 33/38

(52) U.S. Cl. 324/309; 324/318

(57) ABSTRACT

In a magnetic resonance method and system to correct spatial shifts in MR data, at least two measurement data sets are acquired, the additional measurement data set or sets being acquired while switching an additional gradient relative to acquisition of the first measurement data set. For respective corresponding measurement points of the measurement data sets, a phase difference is initially determined from the first measurement data set and at least one additional measurement data set acquired with the additional gradient, with a spatial shift of the measurement points of the first measurement data set being determined from the spatial shift. The magnitude values of the initially measured measurement points are distributed to their correct spatial position corresponding to the determined spatial shifts, so a corrected image data set is created.

### BACKGROUND OF THE INVENTION

1. Field of the Invention

The invention concerns a method to correct distortions in a magnetic resonance (MR image due to inhomogeneities of the basic magnetic field in the MR data acquisition unit and, a magnetic resonance apparatus, and a non-transitory electronically readable data storage medium to implement such a method.

2. Description of the Prior Art

Magnetic resonance is a known modality with which images of the inside of the examination subject can be generated. In simplified terms, for this purpose the examination subject is positioned in a strong, static, homogeneous basic magnetic field (also called a B₀ field) with field strengths of 0.2 Tesla to 7 Tesla or more in a magnetic resonance apparatus (i.e., the MR data acquisition unit thereof), such that the nuclear spins of the examination subject orient along the basic magnetic field. To trigger nuclear magnetic resonances, radio-frequency excitation pulses (RF pulses) are radiated into the examination subject, the triggered nuclear magnetic resonance signals are detected and entered into a memory that represents a domain called c-space, to generate a data set as known as k-space data. MR images are reconstructed or spectroscopy data are determined based on the k-space data. For spatial coding of the measurement (detected) data, rapidly switched gradient magnetic fields are superimposed on the basic magnetic field. The acquired measurement data are digitized and stored in a k-space matrix in the memory as complex numerical values. An associated MR image can be reconstructed from the k-space matrix populated with such values, for example by means of a multidimensional Fourier transformation.

The acquisition of magnetic resonance data from an examination subject that includes magnetic field-influencing interfering objects (for example metallic implants in patients) are not possible with good quality in the region of influence of the interfering object because the interfering object locally distorts the basic magnetic field. Due to the inhomogeneity of the basic magnetic field in the region of influence of the interfering object that accompanies this local distortion, both the excitation of the nuclear spins and the acquisition of the measurement signals (nuclear magnetic resonances) are affected.

However, since metallic implants (for example screws as well) are frequently used in order to fix and/or align breaks or vertebrae, for example, or even in order to replace joints (hip joints, for example), it is nevertheless desired to implement MR measurements on patients with such implants, for example in order to check the progress of the implantation itself or its success (seating of the implant, possible complications such as inflammations). Since other imaging methods (x-rays, for example) are likewise disrupted by the implants and additionally have a poorer soft tissue resolution than MR imaging, the role that such measurements play in MR imaging is becoming increasingly important.

FIG. 1 schematically depicts how such interference can affect the excitation of the nuclear spins. A section of an examination subject divided into seven parallel physical slices p1, p2, p3, p4, p5, p6 and p7 is shown. For example, in a conventional excitation of the physical slice p4, it is the distorted slice p4* that is actually excited due to the influence of the disruption of the magnetic field. Spins from multiple different physical slices are thus actually excited. The signals that are hereby acquired would thus likewise not originate from slice p4, but rather from p4*, and therefore from various physical slices. If not accounted for, this leads to errors (in particular distortions) in the calculation of the image data from the acquired signals.

Various methods have been proposed in order to at least partially address this problem. For example, in U.S. Pat. No. 7,535,227 B1 a method is described in which an interfering object is initially localized in MR exposures, and the region around this interfering object in which the magnetic field is disrupted is corrected by means of a special correction method. In the special correction method, the interference caused by the interfering bodies is modeled using models based on information about the design of the interfering body. The region around the interference object is then corrected under consideration of this modeled interference.

Another method is, for example, the method described by Butts and Pisani in “Reduction of Blurring in View Angle Tilting MRI with Multiple VAT Readouts”, Proc. Intl. Soc. Mag. Reson. Med. 11, p. 99 (2004), which method (improved according to the article) is known as the “View Angle Tilting” (VAT) method. A distortion in the slice (“in-plane”) that is caused by metallic objects is thereby reduced by gradients that are switched (activated) in the slice selection direction during the data acquisition.

In “SEMAC: Slice Encoding for Metal Artifact [sic] Correction in MRI”, Magnetic Resonance in Medicine 62, p. 66-76 (2009), and in US 2010/0033179 A1(there under the designation “SEPI-VAT”), Wenmiao et al, describe a method that corrects artifacts caused by metallic interference objects using a robust slice selection coding of each excited slice with regard to metal-induced inhomogeneities. For this purpose, a VAT method is expanded with an additional phase coding in the slice direction for each slice to be excited, in order to be able to resolve the excitation profile of each slice, which excitation profile is distorted due to the interference. Not only the “in-plane” distortions (as was already the case in VAT) but also distortions between the slices (“through-plane”) are therefore reduced, because the acquired signals can be associated with their actual physical slices via Fourier transformations along the slice selection direction. However, the total measurement time is increased significantly due to the number of additional phase coding steps per slice needed to resolve the respective excitation profiles of each slice. For example, if 16 additional phase codings are implemented in the slice direction, the total measurement time increases by a factor of 16.

A sequence scheme with regard to this known method is depicted in FIG. 2. This corresponds in large part to the scheme for a conventional spin echo-based sequence—for example spin echo (SE) or turbo spin echo (TSE) sequence—in which a radio-frequency excitation pulse RF1 is radiated and a slice selection gradient S1 is simultaneously switched. A radio-frequency refocusing pulse RF2 subsequently follows, possibly with simultaneous switching of an additional slice selection gradient S2, causing an echo signal to be generated that is received by at least one radio-frequency reception antenna in the time period designated AC. For complete spatial coding, a gradient is switched in the readout direction R during the acquisition time period AC and a gradient is switched in the phase coding direction Ph before the beginning of the acquisition time period AC. This scheme is repeated with different coding gradients in the slice direction G_{slice}, readout direction G_{readout} and phase coding direction Gₚₕₐₛₑ until the desired examination volume has been completely scanned. As is indicated at the phase coding gradient Ph in FIG. 2, for this purpose multiple different phase coding gradients are switched given fixed slice coding gradient and readout coding gradient. Gradients known as spoiler gradients Sp can additionally be switched to suppress unwanted signals. In the SEMAC technique, multiple different phase coding gradients are additionally to be switched in the slice direction S-SEMAC per fixed slice coding gradient and readout coding gradient after the radio-frequency refocusing pulse RF2 and before the acquisition time AC, and during the acquisition time AC a gradient is required in the slice direction S-VAT (as was already the case in the VAT technique). As noted, the number of repetitions of this sequence scheme—and therefore the total measurement time—thereby increases by X times given X different phase coding gradients in the slice direction S-SEMAC. For instance, 16 different phase coding gradients are typically used in the slice direction S-SEMAC, whereby the measurement time m increases by 16 times.

In “A Multispectral Three-Dimensional Acquisition Technique for Imaging Near Metal Implants”, MRM, 61, 2009, p. 381-390, Koch et al. describe an additional method to reduce susceptibility artifacts, MAVRIC (Multiple-Acquisitions with Variable Resonance Image Combination), in which multiple three-dimensional fast spin echo MR images are created from multiple exposures with spatially non-selective excitation pulses with varying frequency offsets and are combined into composite MR images. By division into discrete frequency segments and acquisition of these independently of one another, the acquisition of broad frequency ranges enables a coverage of particularly large spectral ranges, wherein at the same time off-resonance effects in the spatial coding are minimized.

In “Z-Selective Multi-Spectral 3D Imaging: A MAVRIC-SEMAC Hybrid”, Magn Reson Med. 2011 Jan; 65(1):71-82; Imaging near metal with a MAVRIC-SEMAC hybrid, Koch et al. describe a hybrid method of the aforementioned SEMAC and MACRIC method in which the MAVRIC method with its separate acquisition with various discrete, overlapping frequency segments is supplemented with the slice coding gradients to be applied in SEMAC upon excitation and acquisition of the data. A method is therefore obtained that, like MAVRIC, uses the spectral overlap of the discrete excitations in order to calculate a unit response and—like SEMAC—is thereby spatially selective.

These known methods either solve the problems with magnetic field distortions only in a limited form or require such a long measurement time that they are not acceptable in clinical routine. The homogeneity of the basic magnetic field can also be disrupted or negatively affected for other reasons. The homogeneous region of the basic magnetic field is normally spatially limited. However it can be desired that, in spite of this, measurements can also be implemented in the no longer homogeneous boundary region of the basic magnetic field, for example since a different arrangement of the examination subject in the magnetic resonance system is not possible. Therefore, there exists a greater need for methods for MR imaging wherein basic magnetic field lacks the ideally desired homogeneity.

### SUMMARY OF THE INVENTION

An object of the present invention is to provide a magnetic resonance system and method, and a non-transitory, electronically readable data storage medium that allow correction of distortions due to inhomogeneities of the basic magnetic field in image data determined by means of magnetic resonance, which correction is reliable and takes place within a clinically acceptable time duration.

A method according to the invention for the correction of distortions due to inhomogeneities of the basic magnetic field in image data determined by means of magnetic resonance includes the following steps:
operate an MR data acquisition unit to excite and acquire a first and at least one additional measurement data set of an examination subject, wherein the first measurement data set and the second measurement data set are excited and acquired such that the switched gradients for each measurement point in an additional measurement data set respectively have an additional gradient in comparison to the switched gradient for each corresponding measurement point in the first measurement data set;
in a computer, reconstruct a first set of a respective magnitude and phase for each measurement point from the first measurement data set and at least one additional set of a respective magnitude and phase for each measurement point from at least one additional measurement data set;
in the computer, determine a respective phase difference between respective corresponding measurement points of the first and at least one additional measurement data set based on the reconstructed phases;
in the computer, determine a spatial shift of each measurement point of at least the first measurement data set on the basis of the respective determined phase difference;
in the computer, distribute the reconstructed magnitude of each measurement point of the first measurement data set at image points of a corrected image data set under consideration of the determined spatial shift; and
make the corrected image data set available as data file from the computer.

The corrected image data set can be stored or displayed.

With the method according to the invention it is possible to correct spatial shifts in the excitation of measurement data. At least two measurement data sets are thereby acquired, wherein the second or possibly each additional measurement data set is acquired while switching an additional gradient relative to the gradient switched during acquisition of the first measurement data set. A phase difference for the respective measurement points of the measurement data sets is initially determined from the first measurement data set acquired without additional gradient and the respective corresponding data point in the at least one additional measurement data set acquired with additional gradients. A spatial shift of the measurement points of the first measurement data set acquired without additional gradients is determined from the determined phase differences. The magnitude values of the initially measured measurement points are distributed to their correct spatial position corresponding to the determined spatial shifts, whereby a corrected image data set is created.

The method thus allows a relatively low-cost and fast—since two measurements per measurement point (voxel) is already sufficient—acquisition of low-distortion image data which also delivers qualitatively high-grade results in regions affected by magnetic field-distorting interfering bodies. The present method can thus be used with particular success in imaging in examination subjects with metallic interfering bodies (for example patients with metallic implants) in order to obtain high-quality image data that is even sufficient for diagnostic purposes.

The spatial shift of each measurement point can be determined by the displacement set of the Fourier transformation. The displacement set of the Fourier transformation states that a multiplication of the signal in k-space S(k) with a linear phase slope results in a displacement in the corresponding spatial direction (here the slice direction z, for example) and vice versa:

FT⁻¹└G(k)e^{-2πika}┘=g(z−a)

The phase difference between the excited measurement signal and acquired measurement signal and the reference measurement signal that is associated with this is accordingly proportional to the shift in the z-direction of the corresponding measurement point (voxel).

The novel method is markedly faster in comparison with others (SEMAC). Instead of the typical 16 measurements in SEMAC, in the novel method two measurements are sufficient in order to obtain a comparable image quality. This is very often decisive for clinical application.

A magnetic resonance system according to the invention has a basic field magnet; a gradient field system; at least one radio-frequency antenna; and a control device to control the gradient field system and the at least one radio-frequency antenna, to receive measurement data acquired by the at least one radio-frequency antenna, to evaluate the measurement data and to create the image data sets; and is designed to
excite and acquire measurement data of a first and at least one additional measurement data set of an examination subject, wherein the first measurement data set and the second measurement data set are excited and acquired such that the switched gradients for each measurement point in an additional measurement data set respectively have an additional gradient in comparison to the switched gradient for each corresponding measurement point in the first measurement data set;
reconstruct a first set of a respective magnitude and phase for each measurement point from the first measurement data set, and at least one additional set of a respective magnitude and phase for each measurement point from at least one additional measurement data set,
determine a respective phase difference between respective corresponding measurement points of the first and at least one additional measurement data set on the basis of the reconstructed phases,
determine a spatial shift of each measurement point of the first measured measurement data set on the basis of the respective determined phase difference,
distribute the reconstructed magnitude of each measurement point of at least the first measurement data set to image points of a corrected image data set under consideration of the determined spatial shift,
display and/or store the corrected image data set.

Furthermore, the magnetic resonance system can be designed to implement any of the additional embodiments of the method according to the invention described above.

A non-transitory, electronically readable data storage medium according to the invention embodies electronically readable control information designed to cause the method described herein to be implemented when executed by a control device of a magnetic resonance system that has access to the storage medium.

### BRIEF DESCRIPTION OF THE DRAWINGS

FIG. 1 schematically shows distortions due to inhomogeneities in the magnetic field of a magnetic resonance system.

FIG. 2 illustrates a SEMAC sequence according to the prior art.

FIG. 3 illustrates a sequence suitable to excite and acquire a first measurement data set according to the present invention.

FIG. 4 illustrates a sequence suitable to excite and acquire an additional measurement data set according to the present invention.

FIG. 5 schematically illustrates the distribution of magnitude values to their corrected spatial position according to the invention.

FIG. 6 is a flowchart of an embodiment of the method according to the invention.

FIG. 7 schematically shows a magnetic resonance system according to an embodiment of the present invention.

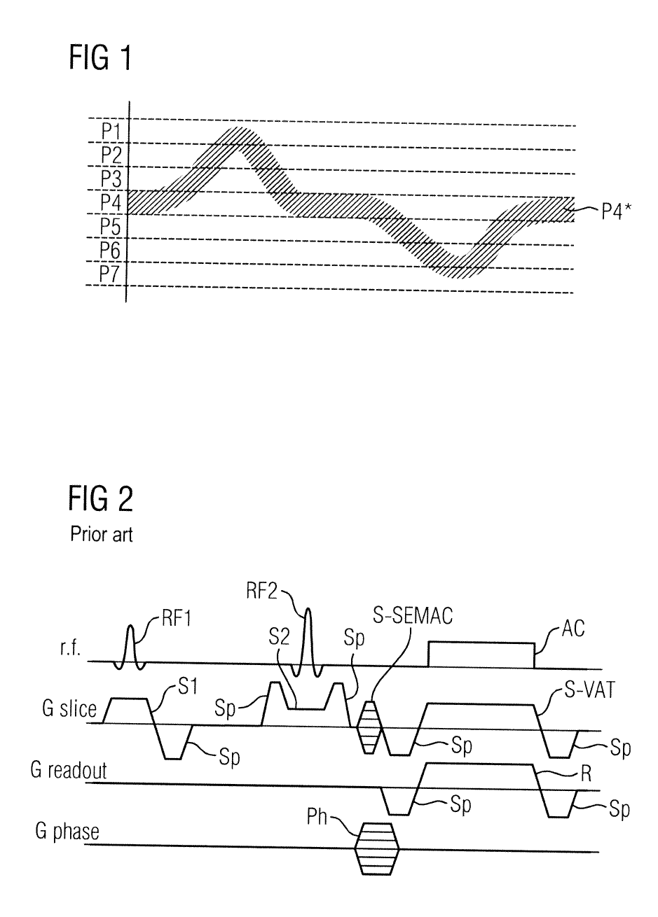

### DESCRIPTION OF THE PREFERRED EMBODIMENTS

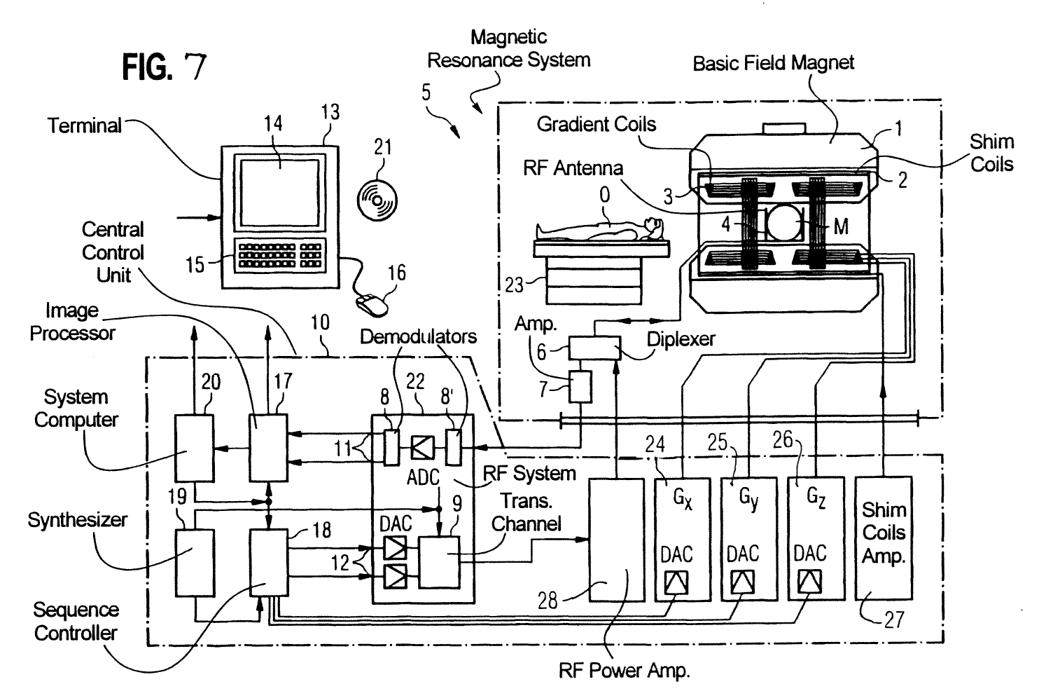

FIG. 7 is a schematic representation of a magnetic resonance system 5 (a magnetic resonance imaging or nuclear magnetic resonance tomography apparatus). A basic magnetic field 1 generates a temporally constant, strong magnetic field for polarization or alignment of the nuclear spins in an examination region of an examination subject U (for example a part of a human body that is to be examined), which lies on a table 23 and is moved into the magnetic resonance system 5. The high homogeneity of the basic magnetic field that is required for the magnetic resonance measurement (data acquisition) is defined in a typically spherical measurement volume M into which the parts of the human body that are to be examined are introduced. Shim plates made of ferromagnetic material are mounted at a suitable point to support the homogeneity requirements, in particular to eliminate temporally invariable influences. Temporally variable influences are eliminated by shim coils 2 and a suitable control 27 for the shim coils 2.

A cylindrical gradient coil system 3 that has three sub-windings is inserted into the basic field magnet 1. Each sub-winding is supplied by a corresponding amplifier 24-26 with current to generate a linear gradient field in the respective direction of a Cartesian coordinate system. The first sub-winding of the gradient field system 3 thereby generates a gradient Gₓ in the x-direction; the second sub-winding generates a gradient G_{y} in the y-direction; and the third sub-winding generates a gradient G_{z} in the z-direction. The amplifiers 24-26 respectively comprise a digital/analog converter (DAC) which is controlled by a sequence controller 18 for time-accurate generation of gradient pulses.

Located within the gradient field system 3 is a radio-frequency antenna 4 that converts the radio-frequency pulses emitted by a radio-frequency power amplifier into an alternating magnetic field so as to excite the nuclei and align the nuclear spins of the subject to be examined, or of the region of the subject that is to be examined. The radio-frequency antenna 4 has one or more RF transmission coils and multiple RF reception coils in the form of a (for example) annular, linear or matrix-like arrangement of coils. The alternating field emanating from the precessing nuclear spins—i.e. normally the nuclear spin echo signals produced by a pulse sequence composed of one or more radio-frequency pulses and one or more gradient pulses—is also transduced by the RF reception coils of the radio-frequency antenna 4 into a voltage (measurement signal) which is supplied via an amplifier 7 to a radio-frequency acquisition channel 8, 8′ of a radio-frequency system 22. The radio-frequency system 22 furthermore has a transmission channel 9 in which the radio-frequency pulses are generated for the excitation of the nuclear magnetic resonance. The respective radio-frequency pulses are digitally represented in the sequence controller 18 as a series of complex numbers based on a pulse sequence provided by the system computer 20. This number series is supplied as a real part and imaginary part via respective inputs 12 to a digital/analog converter (DAC) in the radio-frequency system 22, and from this to the transmission channel 9. In the transmission channel 9 the pulse sequences are modulated on a radio-frequency carrier signal whose basic frequency corresponds to the resonance frequency of the nuclear spins in the measurement volume. The modulated pulse sequences are supplied via an amplifier 28 to the RF transmission coil of the radio-frequency antenna 4.

The switching from transmission operation to reception operation takes place via a transmission/reception diplexer 6. The RF transmission coil of the radio-frequency antenna 4 radiates the radio-frequency pulses for the excitation of the nuclear spins into the measurement volume M and scans resulting echo signals via the RF reception coils. The correspondingly obtained nuclear magnetic resonances signals are phase-sensitively demodulated to an intermediate frequency in a first demodulator 8′ of the acquisition channel of the radio-frequency system 22 and are digitized in the analog/digital converter (ADC). This signal is further demodulated to a frequency of zero. The demodulation to a frequency of zero and the division into real part and imaginary part occurs after the digitization in the digital domain in a second demodulator 8, which emits the demodulated data via outputs 11 to an image computer 17. An MR image is reconstructed by the image computer 17 from the measurement data acquired in such a manner. The administration of the measurement data, the image data and the control programs takes place via the system computer 20 at which measurement data and already processed data can be stored for additional processing. The sequence controller 18 monitors the generation of the respective desired pulse sequences and the corresponding scanning of k-space based on a specification with control programs. In particular, the sequence controller 18 controls the time-accurate switching of the gradients, the emission of the radio-frequency pulses with defined phase amplitude and the reception of the nuclear magnetic resonance signals. The time base for the radio-frequency system 22 and the sequence controller 18 is provided by a synthesizer 19. The selection of corresponding control programs to generate an MR image (which control programs are stored on a DVD 21, for example) as well as the presentation of the generated MR image take place via a terminal 13 that has input means to enable an input (for example a keyboard 15 and/or a mouse 16) and display means (for example a monitor 14) to enable a display.

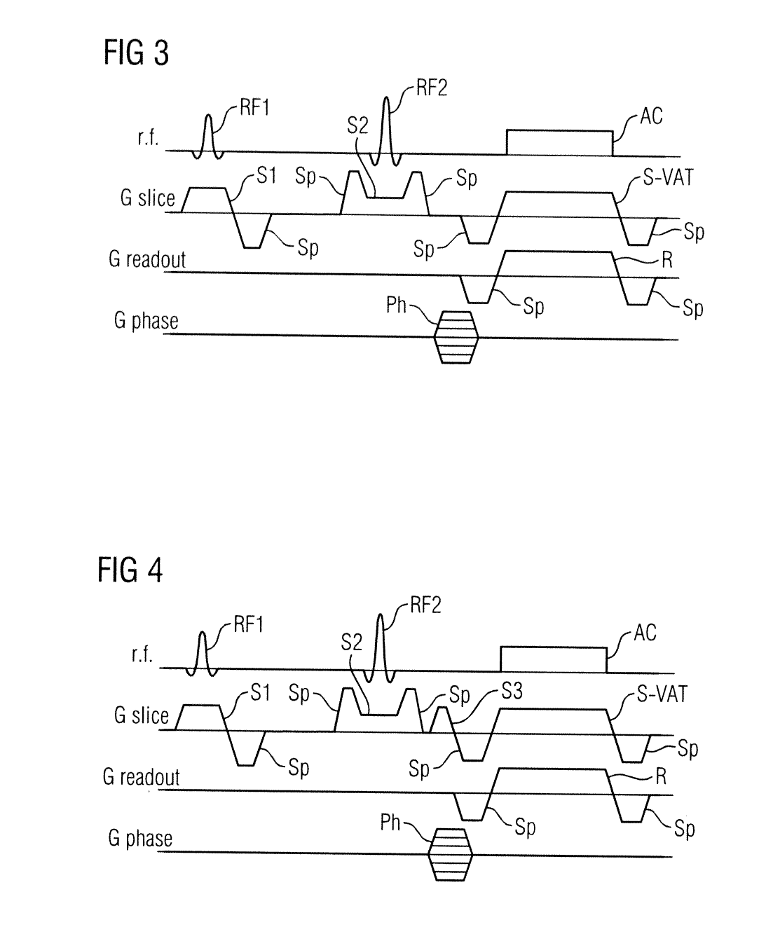

FIGS. 3 and 4 schematically show sequence diagrams as they can be used for the excitation and acquisition of a first measurement data set and an additional measurement data set according to the invention.

FIG. 3 essentially shows a conventional spin echo-based sequence in which a radio-frequency excitation pulse RF1 is radiated and a slice-selection gradient S2 is switched simultaneously. A radio-frequency refocusing pulse RF2 follows after this, possibly with simultaneous switching of an additional slice-selection gradient S2, whereby an echo signal is generated which is acquired in the time period designated with “AC” by means of at least one radio-frequency reception antenna. For complete spatial coding, a gradient is switched in the readout direction R during the acquisition time period AC and a gradient is already switched in the phase coding direction Ph before the beginning of the acquisition time period AC. This scheme is repeated with different coding gradients in the phase coding direction Gₚₕₐₛₑ and in the readout direction G_{readout} until the desired examination volume has been completely scanned. As is also indicated in FIG. 3 at the phase coding gradient Ph, for this multiple different phase coding gradients are to be switched given fixed slice coding gradients and readout coding gradients. In one embodiment of the invention, a gradient (already described above) can additionally also be switched in the slice-selection direction S-VAT during the acquisition time period AC in order to already reduce distortions within a slice in the exposure. Spoiler gradients Sp can be switched to suppress unwanted signals.

FIG. 4 shows a sequence that excites and acquires precisely the same measurement points in a manner similar to the sequence scheme from FIG. 3, but an additional gradient S3 is switched in the slice-selection direction for each measurement point. Each measurement point is therefore acquired once with additional gradient S3 according to the sequence scheme from FIG. 4 and once without additional gradients by means of a conventional sine echo-based sequence according to the sequence from FIG. 3.

In a measurement, the additional gradient S3 in the slice direction enables a phase difference in the slice direction to be determined from both measurements for each measurement point. As described above, this phase difference is used in order to determine and correct a shift of the measurement point in the slice direction by means of the displacement set of the Fourier calculation.

In one embodiment of the invention, additional measurements can be implemented for each measurement point, which measurements are respectively acquired while switching a different additional gradient S3 in order to increase the data set, and thus in order to be able to make statistical calculations (averagings, for example). For example, the displacements determined for various additional gradients can thereby be averaged. Furthermore, the additional data can be used to improve the signal-to-noise ratio (SNR). Measurement data of at least one additional measurement data set can furthermore enter into the corrected image data set in this way.

The additional gradient S3 can be selected such that (for example) an estimated minimum phase shift amounts to −π in the direction of the additional gradient and an estimated maximum phase shift amounts to +π in the direction of the additional gradient. In this way phase jumps are avoided. A spatial integration of the relative phase (“phase unwrapping”) after the extraction of the phase from the respective measurement values for each measurement point can possibly also be used in the determination of the phase difference.

It is also possible to select the additional gradients such that an estimated phase shift that is generated by the additional gradients corresponds to an estimated spatial shift which is greater than an expected spatial shift. A better SNR in the determined phase differences is thereby achieved per measurement point. However, it is hereby suggested that the determined phase differences be subjected to what is known as a “phase unwrapping”.

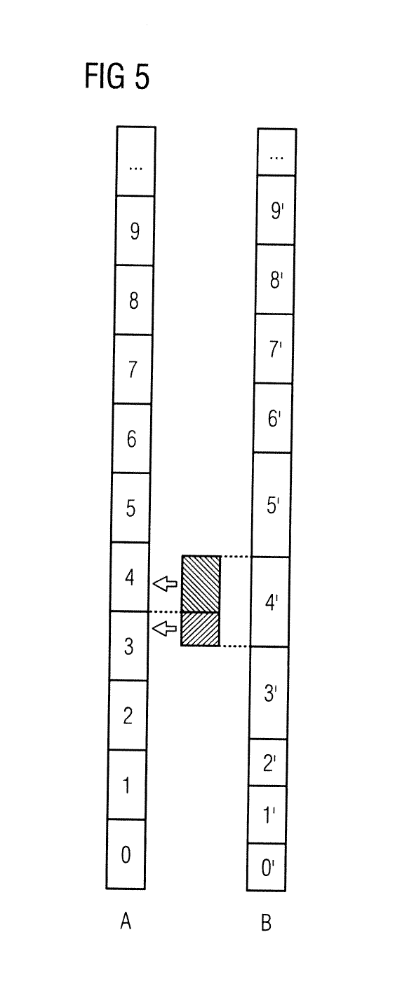

FIG. 5 illustrates a distribution of magnitude values to their corrected spatial position according to the invention. The slice positions z 0, 1, 2, . . . through 9 etc. for the width of a measurement point as they correspond to the corrected image data set are thereby shown in the left column “A”. Each slice position z 0, 1, 2, . . . through 9 etc. is represented in the corrected image data set by a pixel—for example (x,y,z)—at the corresponding position (x,y) in a three-dimensional data set (otherwise analogously).

The slice positions for the measured slices 0′, 1′, 2′, . . . through 9′ etc. for the width of a measurement point are shown in the right column “B”. As is apparent, due to distortions the measured slice positions do not coincide with equidistantly distributed, undistorted slice positions. The magnitude values which were measured for each of the slices 0′, 1′, 2′, . . . through 9′ etc. must therefore be distributed at the slice positions 0, 1, 2, . . . through 9 etc. of the corrected image data set.

From the shifts in the slice direction that are known per measurement point from the determined phase differences, it is known how far and in what direction an individual measurement point has shifted and how severely the slice thickness has increased or decreased. For example, this results from a comparison with the adjacent slices 0′, 1′, 2′, . . . through 9′. In a first approximation a slice edge between two measured slices 0′, 1′, 2′, . . . through 9′ can be taken from this comparison as an average of the determined centers of adjacent slices 0′, 1′, 2′, . . . through 9′. More complicated methods to determine the slice edges (i.e. the boundaries between two adjacent measured slices 0′, 1′, 2′, . . . through 9′) would likewise also be conceivable. The magnitude value of the measurement point can therefore be distributed correctly. This is shown as an example for the measurement point in the measured slice position 4′. The magnitude value of the measurement point of the slice position 4′ is divided up among the corrected slice positions 3 and 4, corresponding to the shown ratio. The overlap with the corrected slice position 3 and that with the corrected slice position 4 (and possibly with each additional corrected slice in question) is determined from the attitude and slice thickness of the slice position 4′. The magnitude value of the measured slice position 4′ is accordingly distributed to the corrected slice positions 3 and 4 in a ratio that corresponds to the ratio of the respective overlaps with one another, as is indicated by the arrows. The method proceeds analogously for the additional measured slice positions. A corrected slice position can therefore be obtained.

In the depiction a rectangular slice profile is assumed. However, the method can analogously also be transferred to other slice profiles.

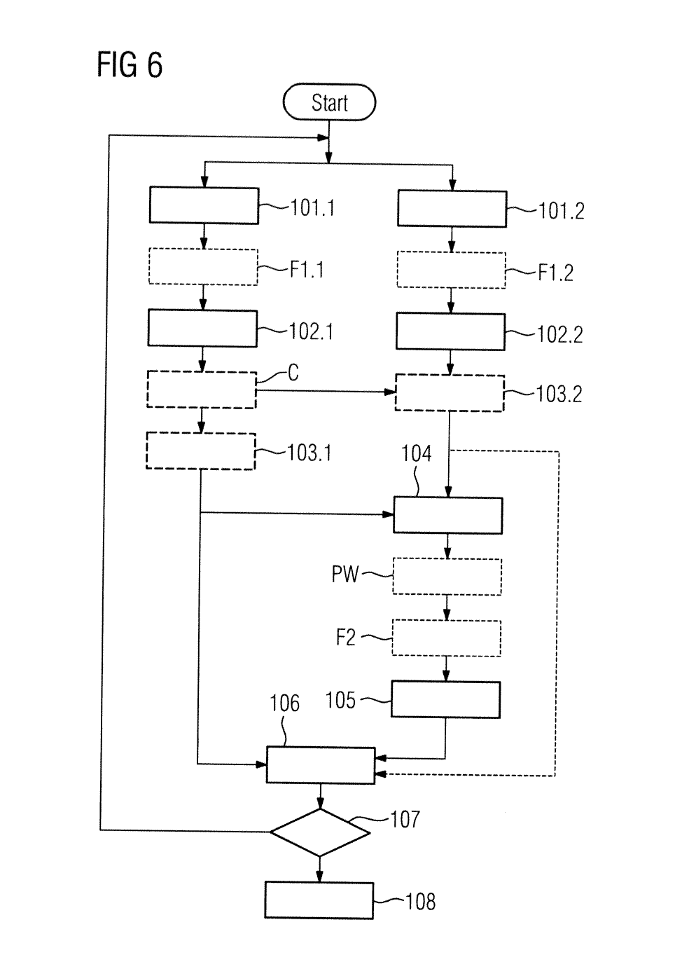

A schematic workflow diagram of a method according to the invention is shown in FIG. 6. In the method to correct distortions due to inhomogeneities of the magnetic field in image data determined by means of magnetic resonance, after the start (“start”) a first measurement data set 101.1 and at least one second, additional measurement data set 101.2 of an examination subject are initially excited and acquired. The first measurement data set 101.1 is excited and acquired (for example by means of a sequence according to FIG. 3) and the second measurement data set 101.2 is excited and acquired (for example according to a sequence according to FIG. 4) such that the switched gradients for each measurement point in an additional measurement data set respectively have an additional gradient in comparison to the switched gradients for each corresponding measurement point in the first measurement data set.

The acquired measurement data are initially still in the form known as k-space data (see above) and can possibly be filtered with suitable filters F1.1 and F1.2 in order to filter out outliers, for example.

For each measurement point of the first and second (possibly filtered) measurement data set 101.1 and 101.2, a set of a respective magnitude and phase value is reconstructed (Blocks 102.1 and 102.2). This typically occurs by complex Fourier transformations of k-space data.

If the first and second measurement data set 101.1 and 101.2 have been excited and acquired by means of a radio-frequency antenna that includes multiple RF transmission coils and multiple RF reception coils, the sensitivity profiles of the multiple RF transmission coils and multiple RF reception coils can preferably be obtained from the first measurement data set 101.1 without additional gradients, or from the second measurement data set 101.2 (C). However, the sensitivity profile can also be determined in another common manner. The determined sets of a respective magnitude and phase of the measurement data acquired with the multiple RF reception coils can now be partially combined (Blocks 103.1 and 103.2) in order to obtain a respective, complete RF reception coil-independent set of magnitude and phase per measurement point of the examination subject. This combination of the sets of a respective magnitude and phase of the various RF reception coils can take place according to the method described by Walsh et al. in “Adaptive Reconstruction of Phased Array MR Imagery”, Magnetic Resonance in Medicine 43:682-690 (2000), for example

However, it is recommended that respectively the same sensitivity profile is used both in the RF reception coil-dependent sets of a respective magnitude and phase for each measurement point from the first measurement data set and in the RF reception coil-dependent sets of a respective magnitude and phase for each measurement point from an additional measurement data set in order to prevent phase errors which can arise given different calculation in the combination of the sets of magnitudes and phases of different RF reception coils.

In a further Step 104, a respective phase difference between respective corresponding measurement points of the first and at least one additional measurement data set is determined on the basis of the reconstructed phases of the sets of a respective magnitude and a phase from Steps 102.1 and 102.2, or (given use of multiple RF reception coils) from Steps 103.1 and 103.2.

The phase values extracted in Step 104 can furthermore be subjected to what is known as a “phase unwrapping”.

Furthermore, the phase values extracted in Step 104 and possibly processed in Step PW can be filtered with an (additional) suitable filter F2 in order to increase the SNR. For example, a possible filter F2 would be what is known as an edge preserving filter.

If multiple additional measurement data sets 101.2 have been excited and acquired (for example given a per-slice excitation and acquisition of the measurement data for this same measured slice), Steps 102.2 or, respectively, 103.2 through 104 are implemented for all or also only for portions of these additional measurement data sets. If multiple phase differences are determined in this manner from multiple measurement data sets 101.2 (Step 104), an optimized (averaged, for example) value can be determined that is based on the additional method. Such an optimized value of the phase difference can naturally also be determined from the multiple determined phase differences by means of another method, for example a linear regression method (“linear fit”) or another optimization method.

A respective spatial shift of each measurement point of the first measured measurement data set is determined in Step 105 based on the respective determined phase differences for corresponding measurement points from the first and the at least one [sic] measurement data set. In particular, this can occur quickly and effectively as described above by means of the displacement set of the Fourier transformation, which associates a spatial shift with each phase difference.

In Step 106, the values of the magnitude for each measurement point of the first measurement data set that are reconstructed in Step 102.1 and in Step 103.1 (given use of multiple RF reception antennas) are distributed to image points of a corrected image data set under consideration of the determined spatial shift of the respective measurement point. In particular, the method can thereby be described as in the preceding with regard to FIG. 5. Additional magnitude values of at least one additional measurement data set (from Steps 102.2 and 103.2) can also be incorporated into the corrected image data set (dashed arrow to 106) to increase the SNR. For example, this can ensue by means of a “sum of squares” method such that a combination of 101.1 (or 103.1) and the values of the at least one additional measurement data set 101.2 (or 103.2) is distributed instead of values from 101.1 (or 103.1).

In an additional Step 107, the corrected image data set is stored at (for example) a system computer of the magnetic resonance system and/or displayed at (for example) a display device of the magnetic resonance system.

If all measurement data to be acquired have already been acquired (query 108), the method ends (“end”). If additional measurement data should still be acquired—for example given a slice-by-slice excitation and acquisition of measurement data, the method begins again with the excitation and acquisition of a first and at least one additional measurement data set 101.1 and 101.2.

The method thus enables a low-cost and rapid generation of corrected, low-distortion image data sets, even in regions with inhomogeneous basic magnetic field in a measurement volume of a magnetic resonance system. The method is therefore particularly suitable for imaging by means of a MR technique in the environment of magnetic field-distorting interfering bodies, for example metallic implants. However, it can also be used in measurements with a basic magnetic field that is inhomogeneous for other reasons.

Although modifications and changes may be suggested by those skilled in the art, it is the intention of the inventors to embody within the patent warranted hereon all changes and modifications as reasonably and properly come within the scope of their contribution to the art.

We claim as our invention:

1. A method to correct distortions due to inhomogeneities of a basic magnetic field in magnetic resonance image data, comprising:
operating a magnetic resonance data acquisition unit, in which a basic magnetic field exhibiting inhomogeneities is generated, to excite nuclear spins in an examination subject at least partially located in said basic magnetic field and to acquire a first measurement data set and at least one additional measurement data set representing magnetic resonance signals resulting from the excitation of said nuclear spins, each of said first and said at least one additional measurement data set comprising a plurality of measurement points, said measurement points in said first measurement data set being acquired by activating a first number of magnetic field gradients in said magnetic resonance data acquisition unit and each measurement point in said at least one additional measurement data set being acquired with a second number of magnetic field gradients being activated in said magnetic resonance data acquisition unit, said second number being larger than said first number;
providing said first measurement data set and said at least one additional measurement data set to a computer and, in said computer, reconstructing a first set of magnitude and phase values for each measurement point in said first measurement data set and a second set of respective magnitude and phase values for each measurement point in said at least one additional measurement data set;
in said computer, determining a phase difference between respective corresponding measurement points of said first and said at least one additional measurement data set from the reconstructed phase values thereof;
in said computer, determining a spatial shift for each measurement point of said first measurement data set from the determined phase difference;
in said computer, distributing the reconstructed magnitude values for the respective measurement points of said first measurement data sets to generate respective image points of a corrected image data set, dependent on the determined spatial shift; and
making said corrected image data set available at an output of said computer as a data file.

2. A method as claimed in claim 1 comprising, from said computer, storing said data file in a memory.

3. A method as claimed in claim 1 comprising generating an image from said corrected image data set in said data file, and displaying said image visually at a display.

4. A method as claimed in claim 1 comprising employing a spin echo-based pulse sequence to operate said magnetic resonance data acquisition unit to excite said nuclear spins and acquire said first measurement data set and said at least one additional measurement data set.

5. A method as claimed in claim 1 comprising determining the spatial shift of said measurement points by Fourier transforming the determined phase differences to generate a shift set.

6. A method as claimed in claim 1 wherein said second number of magnetic field gradients comprises at least one additional gradient with respect to said first number of magnetic field gradients, and comprising operating said magnetic resonance data acquisition unit to generate an inversion pulse after excitation of said nuclear spins and to activate said at least one additional gradient before acquiring said at least one additional measurement data set.

7. A method as claimed in claim 1 wherein said second number of magnetic field gradients comprises at least one additional gradient with respect to said first number of magnetic field gradients, and comprising operating said magnetic resonance data acquisition unit to activate said at least one additional gradient in a slice direction, and determining said spatial shift in said slice direction and generating said corrected image data set to correct said spatial shift in said slice direction.

8. A method as claimed in claim 1 wherein said at least one additional measurement data set comprises further measurement data, and comprising using said further measurement data to generate said corrected image data set.

9. A method as claimed in claim 1 wherein said second number of magnetic field gradients comprises at least one additional gradient with respect to said first number of magnetic field gradients, and operating said magnetic resonance data acquisition unit to activate said at least one additional gradient to produce a minimum phase shift in a direction of said additional gradient of −π, and a maximum phase shift in said direction of said additional gradient of +π.

10. A method as claimed in claim 1 wherein said second number of magnetic field gradients comprises at least one additional gradient with respect to said first number of magnetic field gradients, and operating said magnetic resonance data acquisition unit to activate said additional gradient with a phase shift that corresponds to an estimated spatial shift, which is larger than a phase shift that corresponds to an expected spatial shift.

11. A method as claimed in claim 1 comprising determining said phase difference using phase unwrapping after extraction of the respective phase values for each measurement point in said first measurement data set and said at least one additional measurement data set.

12. A method as claimed in claim 1 comprising operating said magnetic resonance data acquisition unit to acquire said first measurement data set and said at least one additional measurement data set using a radio-frequency antenna in said magnetic resonance data acquisition unit that comprises a plurality of radio-frequency transmission coils and a plurality of radio-frequency acquisition coils.

13. A method as claimed in claim 12 wherein each of said plurality of radio-frequency transmission coils and each of said plurality of radio-frequency reception coils has a sensitivity profile, and using the respective sensitivity profiles of said plurality of radio-frequency transmission coils and said sensitivity profiles of said plurality of radio-frequency reception coils to determine the respective magnitude and phase values for each measurement point in said at least one additional measurement data set, in order to make the respective magnitude and phase values independent of said plurality of radio-frequency reception coils.

14. A magnetic resonance apparatus to correct distortions due to inhomogeneities of a basic magnetic field in magnetic resonance image data, comprising:
a magnetic resonance data acquisition unit comprising a basic field magnet that generates a basic magnetic field exhibiting inhomogeneities, a gradient coil system and a radio-frequency system;
a control unit configured to operate said magnetic resonance data acquisition unit to excite nuclear spins, with said radio-frequency system, in an examination subject at least partially located in said basic magnetic field and to acquire a first measurement data set and at least one additional measurement data set representing magnetic resonance signals resulting from the excitation of said nuclear spins, each of said first and said at least one additional measurement data set comprising a plurality of measurement points, said measurement points in said first measurement data set being acquired by operating said gradient coil system to activate a first number of magnetic field gradients in said magnetic resonance data acquisition unit, and each measurement point in said at least one additional measurement data set being acquired by operating said gradient coil system to activate a second number of magnetic field gradients being in said magnetic resonance data acquisition unit, said second number being larger than said first number;
a computer provided with said first measurement data set and said at least one additional measurement data set, said computer being configured to reconstruct a first set of magnitude and phase values for each measurement point in said first measurement data set and a second set of respective magnitude and phase values for each measurement point in said at least one additional measurement data set;
said computer being configured to determine a phase difference between respective corresponding measurement points of said first and said at least one additional measurement data set from the reconstructed phase values thereof;
said computer being configured to determine a spatial shift for each measurement point of said first measurement data set from the determined phase difference;
said computer being configured to distribute the reconstructed magnitude values for the respective measurement points of said first measurement data sets to generate respective image points of a corrected image data set, dependent on the determined spatial shift; and
said computer being configured to make said corrected image data set available at an output of said computer as a data file.

15. A non-transitory computer-readable data storage medium encoded with programming instructions, said data storage medium being loaded into a computerized control and processing system of a magnetic resonance apparatus comprising a magnetic resonance data acquisition unit, in which a basic magnetic field exhibiting inhomogeneities is generated, said programming instructions causing said computerized control and processing system to:
operate a magnetic resonance data acquisition unit, in which a basic magnetic field exhibiting inhomogeneities is generated, to excite nuclear spins in an examination subject at least partially located in said basic magnetic field and to acquire a first measurement data set and at least one additional measurement data set representing magnetic resonance signals resulting from the excitation of said nuclear spins, each of said first and said at least one additional measurement data set comprising a plurality of measurement points, said measurement points in said first measurement data set being acquired by activating a first number of magnetic field gradients in said magnetic resonance data acquisition unit and each measurement point in said at least one additional measurement data set being acquired with a second number of magnetic field gradients being activated in said magnetic resonance data acquisition unit, said second number being larger than said first number;
reconstruct a first set of magnitude and phase values for each measurement point in said first measurement data set and a second set of respective magnitude and phase values for each measurement point in said at least one additional measurement data set;
determine a phase difference between respective corresponding measurement points of said first and said at least one additional measurement data set from the reconstructed phase values thereof;
determine a spatial shift for each measurement point of said first measurement data set from the determined phase difference;
distribute the reconstructed magnitude values for the respective measurement points of said first measurement data sets to generate respective image points of a corrected image data set, dependent on the determined spatial shift; and
make said corrected image data set available as an output as a data file.
